(19) United States
(12) Patent Application Publication
(10) Pub. No.: US 2007/0161222 A1
(43) Pub. Date: Jul. 12, 2007

(54) METHOD OF FORMING PAD OF SEMICONDUCTOR DEVICE

(76) Inventor: Tae Ho Kim, Incheon (KR)

Correspondence Address: SHERR & NOURSE, PLLC, 620 HERNDON PARKWAY, SUITE 200, HERNDON, VA, 20170, US

(21) Appl. No.: 11/616,734

(22) Filed: Dec. 27, 2006

(30) Foreign Application Priority Data
Dec. 28, 2005 (KR) 10-2005-0131349

(51) Int. Cl. H01L 21/44

(52) U.S. Cl. 438/612; 257/E23.02

(57) ABSTRACT

A method of manufacturing a pad of a semiconductor device. A method may include at least one of the following steps: sequentially depositing a metal layer and an interlayer dielectric layer over a semiconductor substrate; forming a plurality of via holes that expose a metal layer through an interlayer dielectric layer; depositing a second metal layer over an interlayer dielectric layer in order to fill via holes; etching back and/or polishing a second metal layer to form metal plugs in via holes; and/or depositing a top metal layer over metal plugs and an interlayer dielectric layer and changing a pattern in the top metal layer into an arbitrary shape to form a pad.

The present application claims priority under 35 U.S.C. 119 and 35 U.S.C. 365 to Korean Patent Application No. 10-2005-0131349 (filed on Dec. 28, 2005), which is hereby incorporated by reference in its entirety.

### BACKGROUND

Wafers may be mass-produced and may undergo package processing during manufacturing. In package processing, a pad process may protect an internal chip from external environments. In a pad process, an internal chip and apparatus parts may be electrically connected to each other to test an internal circuit by connection through a probe and/or lead lines.

FIGS. 1A to 1E are sectional views illustrating a process of forming a pad in a semiconductor device. As illustrated in FIG. 1A, metal layer 103 may be formed over semiconductor substrate 101. Semiconductor substrate 101 may be an insulating layer (e.g. a PE-TEOS layer) . Metal layer 103 may be formed box-shaped. Inter layer insulating layer 105 may be deposited over metal layer 103. Predetermined portions of deposited interlayer dielectric layer 105 may be selectively etched to form via holes 107 that may expose metal layer 103 through interlayer dielectric layer 105.

As illustrated in FIG. 1B, metal layer 109 may be deposited over interlayer dielectric layer 105 in order to bury via holes 107. As illustrated in FIG. 1C, metal layer 109 is etched back and/or polished to form metal plug 111 in via holes 107. The surface of interlayer dielectric layer 105 may be etched to protrude metal plugs 111 by an arbitrary height.

As illustrated in FIG. 1D, top metal layer 113 may be deposited over protruding metal plugs 111 and interlayer dielectric layer 105. Top metal layer 113 may be a pad illustrated in FIG. 3

As illustrated in FIG. 1E, top metal layer 113 may be part of a pad PAD. Top metal layer 113 (e.g. illustrated in FIGS. 1E and 3), may have a smooth plate structure. With a smooth plate structure, cracks may occur during a probe test or a lead connection. FIG. 1E illustrates a crack from probe tip S1 that may be caused by physical pressure. If a crack is caused, an entire pad may be damaged, which may reduce semiconductor manufacturing yield.

### SUMMARY

Embodiments relate to a method of forming a pad in a semiconductor device. In embodiments, method changes the inside of a top metal into a cross-shaped alignment space.

Embodiments relate to a method of manufacturing a pad of a semiconductor device. A method may include at least one of the following steps: sequentially depositing a metal layer and an interlayer dielectric layer over a semiconductor substrate; forming a plurality of via holes that expose a metal layer through an interlayer dielectric layer; depositing a second metal layer over an interlayer dielectric layer in order to fill via holes; etching back and/or polishing a second metal layer to form metal plugs in via holes; and/or depositing a top metal layer over metal plugs and an interlayer dielectric layer and changing a pattern in the top metal layer into an arbitrary shape to form a pad.

### BRIEF DESCRIPTION OF DRAWINGS

FIGS. 1A to 1E are sectional views illustrating processes of forming pads.

FIG. 2 illustrates a plate-shaped top metal layer.

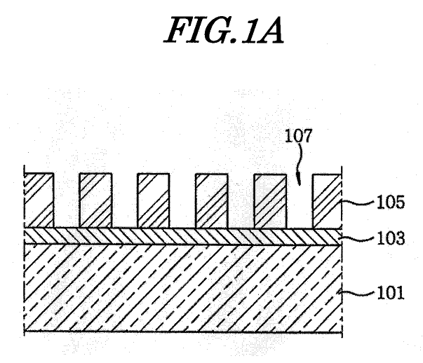

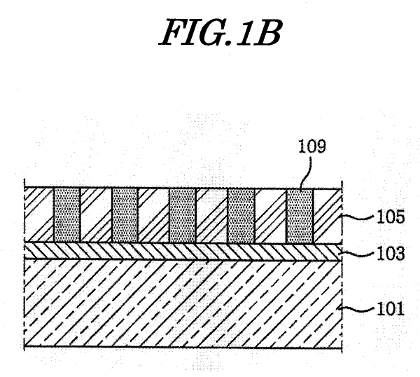

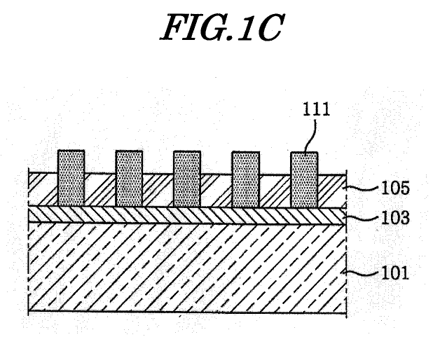

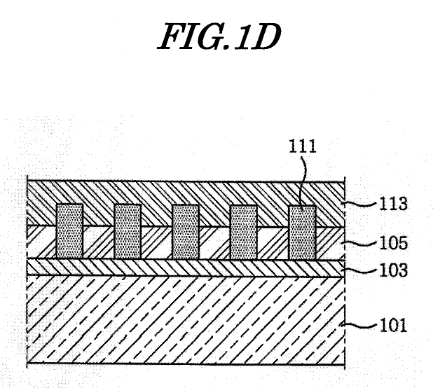

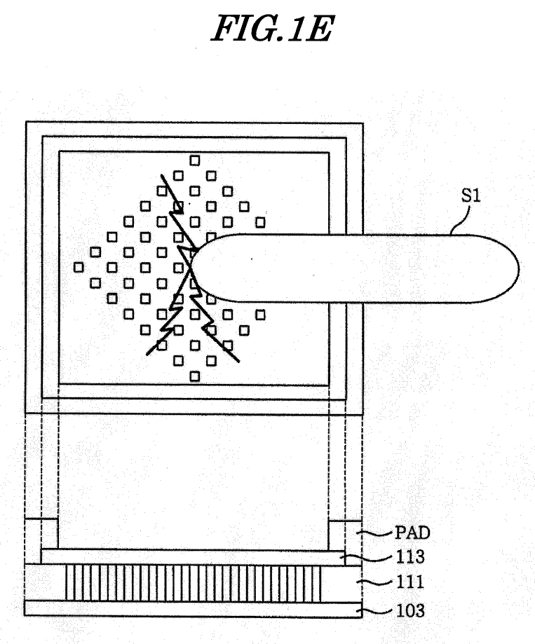

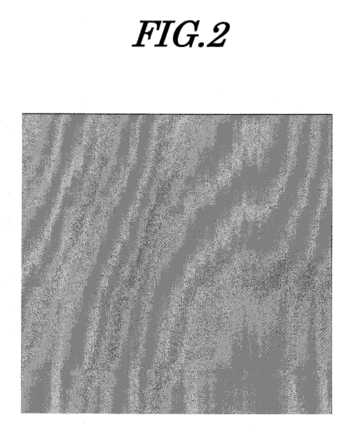

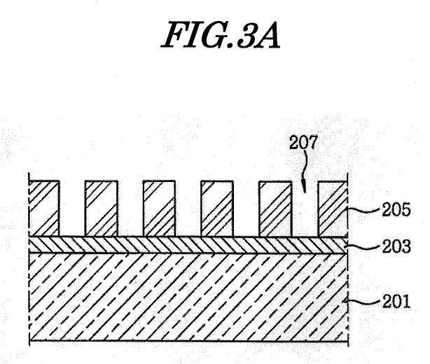

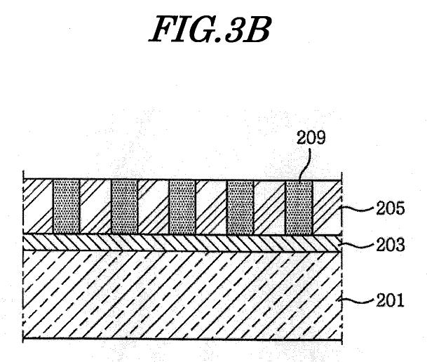

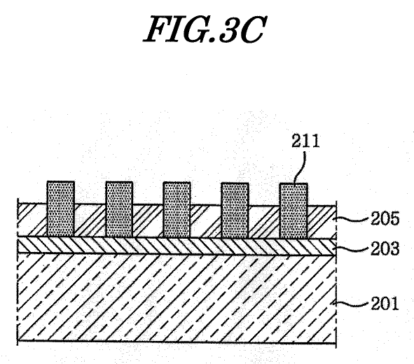

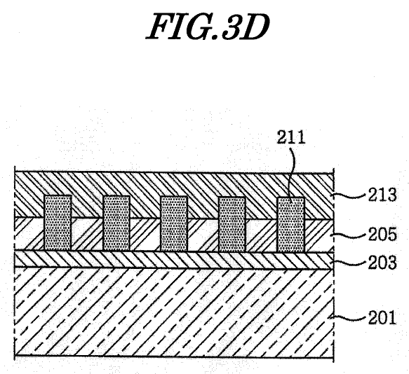

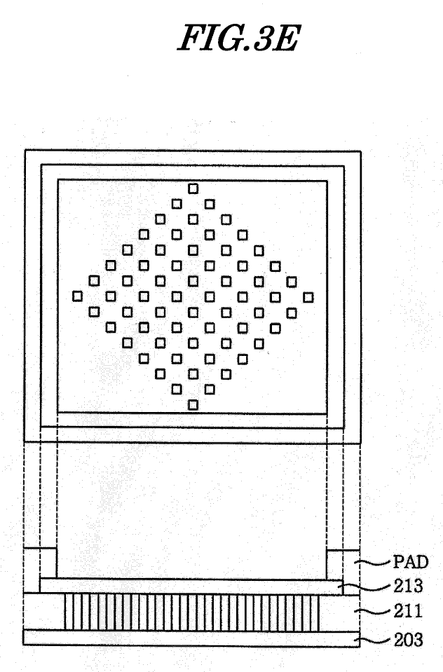

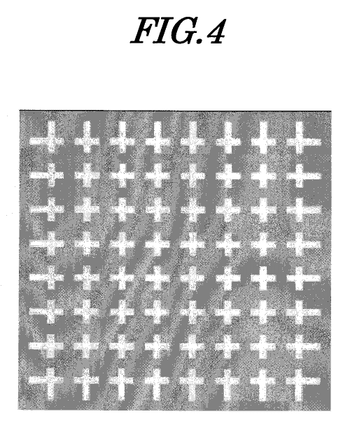

Example FIGS. 3A to 3E are sectional views illustrating processes of forming pads in a semiconductor device, according to embodiments.

Example FIG. 4 illustrates that the inside of a top metal layer includes alignment spaces, according to embodiments.

### DETAILED DESCRIPTION OF THE INVENTION

As illustrated in FIG. 3A, metal layer 203 may be formed over semiconductor substrate 201. Metal layer 203 may be formed as part of a pad structure. Semiconductor substrate 201 may be an insulating layer (e.g. a PE-TEOS layer) . Metal layer 203 may be box-shaped. Interlayer dielectric layer 205 may be formed over metal layer 203. Predetermined portions of deposited interlayer dielectric layer 205 may be selectively etched to form a plurality of via holes 207 that expose metal layer 203 through interlayer dielectric layer 205.

As illustrated in FIG. 3B, metal layer 209 may deposited over the interlayer dielectric layer 205. When metal layer 209 is deposited, via holes 207 may be buried. Metal layer 209 may be polished and/or etched to expose both metal layer 209 formed in via holes 207 and dielectric layer 205.

As illustrated in FIG. 3C, a surface of interlayer dielectric layer 205 may be etched to expose a portion of the sides of metal plugs 211 (e.g. formed from metal layer 209). Dielectric layer 205 may be etched by arbitrary amount to expose an arbitrary portion of the sides of metal plugs 211.

As illustrated in FIG. 3D, top metal layer 213 may be formed over protruding metal plugs 211 and interlayer dielectric layer 205. As illustrated in FIG. 4, the inside of top metal layer 213 may be changed to have at least one alignment space, in accordance with embodiments. In embodiments, an at least one alignment space may have a cross shape (e.g. a “+” shape). In embodiments, an alignment space in top metal layer 213 may be less than about 1 μm. However, one of ordinary skill in the art would appreciate other size ranges. The number of alignment spaces may depend on products and/or processes. In embodiments, a pad structure illustrated in FIG. 3E may include top metal layer 213 with alignment spaces (not shown). Alignment spaces may be formed by etching, in accordance with embodiments. However, other formation techniques of forming alignment spaces may be use, in accordance with embodiments.

In pad structure, according to embodiments, with alignment spaces may protect top metal layer 213 from cracking damage. For example, if a crack is formed by physical pressure during a probe test and/or a lead connection, the crack may be prevented from spreading to the entire pad, in accordance with embodiments. A crack may be prevented from spreading to an entire pad, depending on the shape (e.g. a cross-shape), size (e.g. 1 μm), interval, or distribution of alignment spaces, in accordance with embodiments. In embodiments, yield of a manufacturing process may be improved.

It will be obvious and apparent to those skilled in the art that various modifications and variations can be made in the embodiments disclosed. Thus, it is intended that the disclosed embodiments covers the obvious and apparent modifications and variations, provided that they are within the scope of the appended claims and their equivalents.

What is claimed is:

1. A method of manufacturing a pad in a semiconductor device, comprising:
forming an upper metal layer over a semiconductor substrate, wherein the upper metal layer is a contact portion of a pad structure; and
forming at least one alignment space in the upper metal layer.

2. The method of claim 1, wherein said at least one alignment space has a cross shape.

3. The method of claim 1, wherein said at least one alignment space is less than about 1 μm.

4. The method of claim 1, wherein said at least one alignment space is configured to prevent cracks from spreading across an entire pad when cracking occurs.

5. The method of claim 1, wherein said at least one alignment space is a plurality of alignment spaces formed in a pattern.

6. The method of claim 1, comprising:
forming a first metal layer over a semiconductor substrate; and
forming a dielectric layer over the first metal layer;
forming a plurality of via holes in the dielectric layer to expose the first metal layer; and
forming metal plugs in the via holes that protrude out of the via holes, wherein the upper metal layer is formed over the metal plugs and the dielectric layer.

7. The method of claim 6, wherein the dielectric layer is an interlayer dielectric layer.

8. The method of claim 6, comprising:
forming a second metal layer over the dielectric layer and inside the via holes;
removing a portion of the second metal layer to expose the dielectric layer to form metal plugs in the via holes; and
removing a portion of the dielectric layer to make the metal plugs protrude from the dielectric layer.

9. The method of claim 8, wherein said removing a portion of the second metal layer comprises at least one of etching and polishing.

10. The method of claim 8, wherein said removing a portion of the dielectric layer comprises etching the dielectric layer.

11. An apparatus comprising a pad in a semiconductor device, comprising:
an upper metal layer formed over a semiconductor substrate, wherein the upper metal layer is a contact portion of a pad structure; and
at least one alignment space formed in the upper metal layer.

12. The apparatus of claim 11, wherein said at least one alignment space has a cross shape.

13. The apparatus of claim 11, wherein said at least one alignment space is less than about 1 μm.

14. The apparatus of claim 11, wherein said at least one alignment space is configured to prevent cracks from spreading across an entire pad when cracking occurs.

15. The apparatus of claim 11, wherein said at least one alignment space is a plurality of alignment spaces formed in a pattern.

16. The apparatus of claim 11, comprising:
a first metal layer formed over a semiconductor substrate; and
a dielectric layer formed over the first metal layer;
a plurality of via holes formed in the dielectric layer to expose the first metal layer; and
metal plugs formed in the via holes that protrude out of the via holes, wherein the upper metal layer is formed over the metal plugs and the dielectric layer.

17. The apparatus of claim 16, wherein the dielectric layer is an interlayer dielectric layer.

18. The apparatus of claim 16, comprising a second metal layer formed over the dielectric layer and inside the via holes, wherein:
a portion of the second metal layer is removed to expose the dielectric layer and form metal plugs in the via holes; and
a portion of the dielectric layer is removed to make the metal plugs protrude from the dielectric layer.

19. The apparatus of claim 18, wherein the portion of the second metal layer is removed by at least one of etching and polishing.

20. The apparatus of claim 18, wherein the portion of the dielectric layer is removed by etching the dielectric layer.
